(19) United States
(12) Patent Application Publication
(10) Pub. No.: US 2003/0201916 A1
(43) Pub. Date: Oct. 30, 2003

(54) Keyboard tone data transfer

(76) Inventor: Robert H. Nathan, Atlanta, GA (US)

Correspondence Address: PAUL W. MARTIN, LAW DEPARTMENT, WHQ-5E, 1700 S. PATTERSON BLVD., DAYTON, OH, 45479-0001, US

(21) Appl. No.: 10/132,236

(22) Filed: Apr. 26, 2002

(51) Int. Cl. H03M 11/00; H03K 17/94

(52) U.S. Cl. 341/22; 345/168; 379/93.28

(57) ABSTRACT

A method of generating a tone from a human interface device (HID) or keyboard (including a speaker) responsive to manipulation of a key on the HID is described. A key manipulation at the HID is detected and a keyboard tone usage corresponding to the detected key manipulation is determined. A tone is generated from the keyboard speaker responsive to the detected key manipulation and based on the keyboard tone usage. The keyboard tone usage specifies the volume, duration, and frequency of the generated tone Another aspect includes a method of configuring the keyboard to generate a tone responsive to manipulation of a key. A connected keyboard device is detected and a keyboard tone usage corresponding to the detected keyboard device is determined. The keyboard tone usage is stored on the keyboard device specifying the tone to be generated.

### FIELD OF THE INVENTION

The present invention is related to a method of and apparatus for keyboard tone data transfer; and more particularly, to a method and apparatus for keyboard tone data transfer using the Universal Serial Bus (USB) protocol.

### BACKGROUND ART

Point-of-sale keyboards and other peripherals may be equipped with a speaker or sound generation device to provide auditory feedback to a user. When the user presses a key on the keyboard, the speaker emits a “click” sound providing auditory reinforcement to the user. That is, the user is able to tell whether they struck a key without having to look at the keyboard. Application programs or executable software may also use the speaker to generate a tone indicating an error occurrence to the user. For example, if the user clicks an incorrect key sequence or provides an incorrect entry order, an error tone, preferably one different from the key click tone, is generated to inform the user.

It is known in the art to connect keyboards, or other peripheral devices capable of generating sound, to a computer by using different physical or logical connections. If the universal serial bus (USB) is the connection mechanism, tone information is formed into packets with certain common USB characteristics and other characteristics specific to tone generation.

The general protocol for transmitting data over USB is defined in specifications licensed by the USB Implementer's Forum (USBIF) or published by the USB device working group (DWG) on the public Web site, i.e., http://www.usb.org. Existing USB protocol definitions permit many different ways of transmitting data For example, the USBIF defines four types of data transmission: control, interrupt, bulk, and isochronous. Each type of data transmission includes specific characteristics. A USB device may transmit data using one or more of the data transmission types, also known as endpoint types.

The USB DWG has defined several classes of devices. Each class uses a specified set of the above described endpoint types. Each class further specifies the format of the data to be transmitted. One such defined class is the human interface device (HID) class. The HID class, as defined by the USB DWG and specified in the Device Class Definition for Human Interface Devices (HID), hereinafter the HID Specification, version 1.11 published Jun. 27, 2001 by the USBIF and available from http://www.usb.org, specifies some, but not all, of the characteristics of the transmitted data. More particularly, the HID class specifies a mechanism by which a device designer can provide extensions to the HID specification. These extensions are called usages, and a HID class device sends and receives data using either published, pre-defined usages, privately invented usages, or a combination of public and private usages. Furthermore, a HID class device formats data in a manner causing these usages to have specific, useful meaning to the host computer.

The specification for USB-based audio devices is found in the USB Audio Device Class specification documents version 1.0, available from the USB Implementer's Forum, Inc. at http://www.usb.org. However, the specification found in the USB Audio Device Class Specification is too burdensome. That is, it is not necessary to implement the entire USB Audio Specification for simply generating a tone at a keyboard.

There is a need in the art for defining custom characteristics of USB data transmission by which sound generation data may be transmitted.

Further, because the device, i.e., the keyboard or keypad having an integrated speaker, is a HID, there is a need to provide a custom extension of the HID specification to enable the transmission and generation of tones to/from HIDs.

A specific example of keyboard sound generation in the prior art is now provided to detail the importance of providing key click feedback to users. Although the example describes a retail scenario, the below-described present invention is not to be limited to such an implementation. There are numerous HIDs which could benefit from the ability to receive tone generation information and generate or emit tones.

It is known in the art to generate a tone from a computer speaker responsive to a user manipulating keys on a keyboard connected to a computer. As the user manipulates or clicks keys, a key click sound is emitted from the computer speaker. The key click sound provides important feedback information to the user similar to the tactile feedback provided when a keyboard has raised dimples on certain keys, e.g., the ‘f’ and ‘j’ keys, to indicate finger position to a user without requiring the user to look at their finger position on the keyboard.

As such, the user may rely on hearing a key click sound when entering data on a keyboard, or keypad, without having to look at either the keyboard or a display to verify that information was entered. The feedback is important in retail establishments to ensure that cashiers or clerks are entering all sales and in order to speed the process of checking out customers, i.e., shortening checkout time.

A typical retail checkout stand 100 is now described with reference to FIG. 1. A customer (not shown) places items, e.g., grocery item 102, to be purchased on a conveyor belt 104. A cashier or clerk 106 moves grocery item 102 past a bar code scanner 108 to scan a bar code 110 on the grocery item to identify the item to be purchased by the customer. The scanner 108 transmits a signal representing the scanned bar code 110 to a computer system 112 (dashed line) located inside a cabinet 114 forming a part of checkout stand 100. The computer system 112 includes a speaker 113 for generating the aforementioned tones. In an alternate embodiment, the computer system 112 may be located remote from checkout stand 100 and send and receive signals over a network connection to the checkout stand.

If the item 102 does not have a bar code 110, or if the bar code scanner is unable to scan the bar code, clerk 106 must manually enter the bar code for the item using a keyboard 116. Clerk 106 manipulates keys on keyboard 116, connected to computer system 112, to provide the bar code information to the computer system

Upon receipt of the bar code information, from either keyboard 116 or bar code scanner 108, computer system 112 performs a lookup to identify the item 102 and retrieves item information, e.g., item name and price information from memory.

Computer system 112 stores purchased item information and accumulates a total purchase price for the items in memory. The purchased item information and cumulative total purchase price are transmitted to a display 118 (described in detail below) for display to the customer and clerk 106. The item information is additionally transmitted to a receipt printer 120 for printing a receipt 122 to be provided to the customer at the completion of the transaction.

After the clerk 106 has scanned or manually entered (via keyboard 116) item information for all items, the customer tenders an amount of money to the clerk in payment. The money tendered may be in the form of cash, check, or debit or credit via a card reader 124 attached to checkout stand 100. Additionally, the customer may tender coupons, or other forms of payment to clerk 106. Card reader 124 is a typical card reader as is known to persons of skill in this art.

In operation, and as briefly described above, clerk 106 uses keyboard 116 to enter bar code information from items to be purchased. In some instances, the clerk 106 enters item information directly, e.g., item type and price information. As the clerk 106 manipulates the keys on the keyboard 116, the computer system 112 receives a signal from the keyboard and generates a tone or key click using speaker 113 to audibly indicate the manipulation of a key. If a particular key sequence is expected to be received by the computer system 112 and the clerk 106 does not enter the proper sequence, the computer system may generate a different tone from speaker 113. For example, a “dead” click or error tone may be generated if the clerk 106 input using keyboard 116 has exceeded a field or entry capacity. The error tone in such a case would indicate that a key on the keyboard 116 was activated, but there was a problem with the input and the clerk 106 needs to view the display 118 to resolve the problem.

Using speaker-generated tones, the clerk 106 is able to scan and key in items without being required to focus on the keyboard. If a problem arises, the clerk 106 is alerted audibly by speaker 113. However, as described above, in the typical retail configuration, the computer system 112 and included speaker 113 are located away from the keyboard 116 and display 118. In such a configuration, generated tones are either muffled or not heard by clerk 106 during the normal course of business and are frequently drowned out by ambient or background noise. As a consequence, missed or erroneous keystrokes at keyboard 116 go unnoticed and much time is lost due to clerk 106 having to backtrack through a transaction sequence to resolve the error, if the error is noticed. If the error is unnoticed, money is lost and inventory counts are incorrect as the item 102 was never properly paid for or accounted for by the computer system 112.

Additionally problematic, if the clerk 106 notices the error tone, the clerk is likely to have his attention directed to the computer system 112 instead of keyboard 116 or display 118 where the error can be resolved. Therefore, it is important that the sound is generated from keyboard 116 wherein the error is directly related, i.e., an incorrect key entry by clerk 106.

### DISCLOSURE/SUMMARY OF THE INVENTION

It is therefore an object of the present invention to provide a method and apparatus for generating a tone from a USB-based human interface device having a speaker.

Another object of the present invention is to provide a method and apparatus for generating a tone from a USB-based keyboard having a speaker and responsive to manipulation of a key on the keyboard.

Another object of the present invention is to set the tone to be generated by a USB-based keyboard having a speaker and responsive to manipulation of a key on the keyboard.

Another object of the present invention is to provide a method and apparatus for transferring key click information to a keyboard having a speaker and being connected by universal serial bus to a computer.

Another object of the present invention is to provide a method and apparatus for transferring error tone information to a keyboard having a speaker and being connected by universal serial bus to a computer.

In accordance with a method aspect a tone is generated from a keyboard responsive to manipulation of a key on the keyboard. The keyboard includes a speaker. A key manipulation at the keyboard is detected and a keyboard tone usage corresponding to the detected key manipulation is determined. A tone is generated from the keyboard speaker responsive to the detected key manipulation and based on the keyboard tone usage. The keyboard tone usage may be a key click info usage and an error tone usage.

Another method aspect includes setting a keyboard to generate a tone responsive to manipulation of a key on the keyboard including a speaker. A connected keyboard device having a speaker is detected. A keyboard tone usage corresponding to the detected keyboard device is determined and the keyboard tone usage is transmitted to the keyboard device. The keyboard tone usage includes a volume usage, a duration usage, and a frequency usage for generating the tone from the speaker.

In an apparatus aspect, a keyboard generates a tone responsive to manipulation of a key on the keyboard. The keyboard includes a plurality of keys, a programmable component, a data connection, and a speaker. The programmable component is responsive to key manipulation to drive the speaker to generate a tone. The data connection is adapted to interface with a computer and pass a keyboard tone usage. The speaker is coupled to the programmable component which derives a signal responsive to key manipulation and based on the keyboard tone usage.

An additional aspect is a computer readable medium including at least one sequence of machine executable instructions and at least one keyboard tone usage. Execution of the instructions by one or more processors causes the one or more processors to detect a connected keyboard device having a speaker, determine a keyboard tone usage corresponding to the detected keyboard device. The keyboard tone usage is transmitted to the keyboard device.

A computer system aspect includes a processor, a keyboard, and a memory. The keyboard is coupled to the processor and has a speaker and a programmable component. The memory is coupled to the processor and has stored therein sequences of instructions, which when executed by the processor, cause the processor to determine keyboard identifying information. The instructions further cause the processor to determine a keyboard tone usage corresponding to the keyboard identifying information. The keyboard tone usage is transmitted to the programmable component of the keyboard.

As used herein, the term “serial” refers to the “RS-232 family” of interfaces and the term “USB” refers to the standard(s) developed and published by the USBIF (Universal Serial Bus Implementer's Forum), recently incorporated under that name.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious respects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein.

FIG. 1 is a diagram of a prior art system in use;

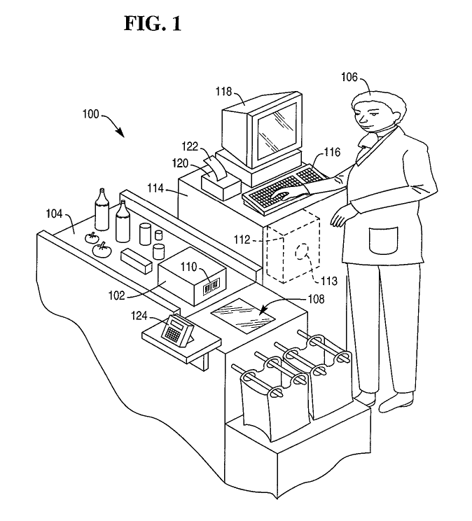

FIG. 2 is a high level block diagram of a computer system useable with a preferred embodiment of the present invention; and

FIG. 3 is a functional block diagram of a keyboard useable in conjunction with the computer system of FIG. 2.

### BEST MODE FOR CARRYING OUT THE INVENTION

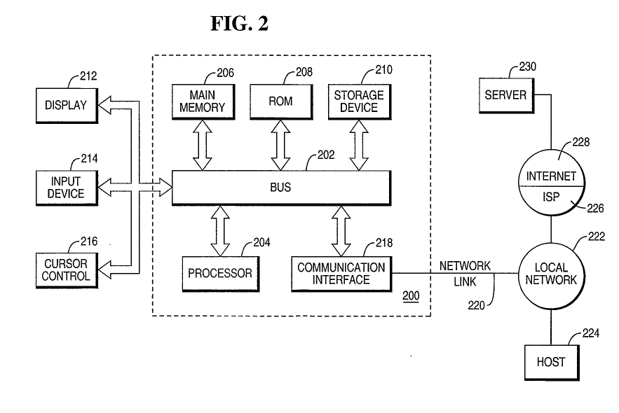

A computer system useable with a preferred embodiment of the present invention is now described with reference to FIG. 2.

Hardware Overview

FIG. 2 is a block diagram illustrating an exemplary computer system 200 in conjunction with which a preferred embodiment of the invention may operate and be implemented. The present invention is usable with currently available personal computers, mini-mainframes and other computers having USB connectivity.

Computer system 200 includes a bus 202 or other communication mechanism for communicating information, and a processor 204 coupled with the bus 202 for processing information. Computer system 200 also includes a main memory 206, such as a random access memory (RAM) or other dynamic storage device, coupled to the bus 202 for storing USB usages, e.g., keyboard tone, key click tone, and error tone usages, frequency, volume, and duration values, data, and instructions to be executed by processor 204. Main memory 206 also may be used for storing temporary variables or other intermediate information during execution of instructions to be executed by processor 204. Computer system 200 further includes a read only memory (ROM) 208 or other static storage device coupled to the bus 202 for storing static information and instructions for the processor 204. A storage device 210, such as a magnetic disk or optical disk, is provided and coupled to the bus 202 for storing USB usages, frequency, volume, and duration values, data, and instructions.

Computer system 200 may be coupled via the bus 202 to a display 212, such as a cathode ray tube (CRT) or a flat panel display, for displaying information to a user. An input device or human interface device (HID) 214, e.g., a keyboard or keypad including alphanumeric and function keys, is coupled to computer system 200 for communicating information and command selections to processor 204. HID 214 is a USB-based device and communicates with computer system 200 using the USB protocol as is known to persons of skill in the art and as modified below in accordance with the present invention. Another type of human interface device is cursor control 216, such as a mouse, a trackball, or cursor direction keys for communicating direction information and command selections to processor 204 and for controlling cursor movement on the display 212. This input device typically has two degrees of freedom in two axes, a first axis (e.g., x) and a second axis (e.g., y) allowing the device to specify positions in a plane.

The invention is related to the use of computer system 200, such as the illustrated system of FIG. 2, to transmit tone information in the form of novel USB HID usages, i.e., keyboard tone usage, key click info usage, error tone usage, frequency usage, duration usage, and volume usage, to HID 214. According to one embodiment of the invention, the keyboard tone usages are transmitted to HID 214 by computer system 200 in response to processor 204 executing sequences of instructions contained in main memory 206. Such instructions may be read into main memory 206 from another computer-readable medium, such as storage device 210.

However, the computer-readable medium is not limited to devices such as storage device 210. For example, the computer-readable medium may include a floppy disk, a flexible disk, hard disk, magnetic tape, or any other magnetic medium, a compact disc (CD-ROM), any other optical medium, punch cards, paper tape, any other physical medium with patterns of holes, a random access memory (RAM), a programmable ROM (PROM), an erasable programmable ROM (EPROM), a flash-EPROM, any other memory chip or cartridge, a carrier wave embodied in an electrical, electromagnetic, infrared, or optical signal, or any other medium from which a computer can read. Execution of the sequences of instructions contained in the main memory 206 causes the processor 204 to perform the steps described below. In alternative embodiments, hard-wired circuitry may be used in place of or in combination with computer software instructions to implement the invention. Thus, embodiments of the invention are not limited to any specific combination of hardware circuitry and software.

Computer system 200 also includes a communication interface 218 coupled to the bus 202. Communication interface 208 provides two-way data communication as is known. For example, communication interface 218 may be an integrated services digital network (ISDN) card, a digital subscriber line (DSL) card, or a modem to provide a data communication connection to a corresponding type of telephone line. As another example, communication interface 218 may be a local area network (LAN) card to provide a data communication connection to a compatible LAN. Wireless links may also be implemented. In any such implementation, communication interface 218 sends and receives electrical, electromagnetic or optical signals which carry digital data streams representing various types of information. Of particular note, the communications through interface 218 may permit transmission or receipt of USB keyboard tone usages and tone information. For example, two or more computer systems 200 may be networked together in a conventional manner with each using the communication interface 218.

Network link 220 typically provides data communication through one or more networks to other data devices. For example, network link 220 may provide a connection through local network 222 to a host computer 224 or to data equipment operated by an Internet Service Provider (ISP) 226. ISP 226 in turn provides data communication services through the world wide packet data communication network now commonly referred to as the “Internet” 228. Local network 222 and Internet 228 both use electrical, electromagnetic or optical signals which carry digital data streams. The signals through the various networks and the signals on network link 220 and through communication interface 218, which carry the digital data to and from computer system 200, are exemplary forms of carrier waves transporting the information.

Computer system 200 can send messages and receive data, including program code, through the network(s), network link 220 and communication interface 218. In the Internet example, a server 230 might transmit a requested code for an application program through Internet 228, ISP 226, local network 222 and communication interface 218. In accordance with the invention, one such downloaded application provides for transmitting keyboard tone usages to USB-based HID 214 for specification of tone generation information.

The received code may be executed by processor 204 as it is received, and/or stored in storage device 210, or other non-volatile storage for later execution. In this manner, computer system 200 may obtain application code in the form of a carrier wave.

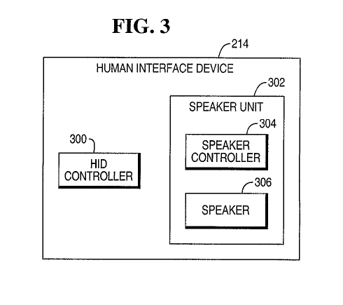

USB-based HID or keyboard 214 is now described in detail with reference to FIG. 3. HID 214 is connected to computer system 200 via USB. As depicted in FIG. 3, HID 214 includes a HID controller 300 for receiving commands from and transmitting information to computer system 200 using the USB and a speaker unit 302 for generating tones. As described in detail below, HID controller 300 receives keyboard tone usages, i.e., key click info usage and error tone usage, from computer system 200 and transmits the usages to speaker unit 302 for generation of the appropriate tone. HID controller 300 is a programmable logic device, e.g., a field programmable gate array (FPGA) and is known to persons of skill in the art.

Speaker unit 302 includes a speaker controller 304 for receiving keyboard tone usages (described in detail below) from HID controller 300 and driving a speaker 306 at a specific frequency and volume, and for a specific duration. Speaker controller 304 is a programmable logic device similar to HID controller 300, e.g., a field programmable gate array (FPGA). Speaker 306 is known to persons of skill in the art and is coupled to speaker controller 304.

In an alternate embodiment, speaker controller 304 may be combined with and made a part of HID controller 300 without detracting from the present invention. In such an implementation, HID controller 300 directly drives speaker 306.

In another alternate embodiment, speaker unit 302 is a separate device from HID 214. In such an implementation, speaker unit 302 may be directly connected to HID 214 and receive keyboard tone usages from HID 214 using a USB connection.

In still another alternate embodiment, speaker unit 302 is a separate device, as described above, and may be directly connected to computer system 200. Speaker unit 302, in such a configuration, receives keyboard tone usages from computer system 200 >using a USB connection.

A detailed description of the keyboard tone usages of the present invention is now provided.

The present invention defines the parameters of sound generation for a USB keyboard, having sound generation capabilities, is being transmitted using custom HID , usages called keyboard tone, key click info, error tone, frequency, duration, and volume. The keyboard-tone usage acts as a collection refining the meaning of the other usages as pertaining to a sound generator associated with a keyboard or other peripheral. The keyboard tone usage is a top-level class and is not always transmitted to HID 214. In accordance with the HID Specification, top-level usages, such as the keyboard tone usage, are transmitted in report descriptors at computer system 200 startup and/or connection of a HID device to the computer system. Report identifiers, as specified in the HID Specification, are used to correlate usages to reports but are not required for operation of the present invention. One or the other of the key click info usage or the error tone usage are transmitted as a type of keyboard tone usage class.

The key click info usage acts as a collection further refining the meaning of the frequency, duration, and volume usages as pertaining to a sound to be generated from speaker 306 when a key on the keyboard 214 is pressed. The key click info usage, including the frequency, duration, and volume specifications, are stored at speaker controller 304. When a key on keyboard 214 is pressed by a user, HID controller 300 transmits a signal to inform speaker controller 304 of the key press. Speaker controller 304 determines, based on the stored key click info usage, whether and what note to drive speaker 306 to emit.

The error tone usage acts as a collection further refining the meaning of the frequency, duration, and volume usages as pertaining to a sound to be immediately generated from speaker 306. The tone generated in response to receipt of an error tone usage indicates that an error has occurred and directs the user's attention to the error.

On receipt of an error tone usage, HID controller 300 transmits the error tone usage to speaker controller 304. Responsive to receiving the error tone usage, speaker controller 304 determines, based on the received error tone usage, whether and what note to drive speaker 306 to emit.

In a preferred embodiment, frequency usage is defined as a note number from 1 to 127 corresponding to notes of a scale between 27.5 Hz and 42.192 kilohertz (kHz). The note number is defined by the following equation:

$$f \approx 27.5 \times {2}^{N / 12} \qquad \text{(Equation 1)}$$

The note number sent from computer system 200 to speaker controller 304 is selected by rounding the requested frequency to the nearest frequency number given by Table 1 below.

TABLE 1

| Note | N | freq | N | freq | N | freq | N | freq | N | freq | N | freq |
|---|---|---|---|---|---|---|---|---|---|---|---|---|
| A | 0 | 28 | 24 | 110 | 48 | 440 | 72 | 1760 | 96 | 7040 | 120 | 28160 |
| Bb | 1 | 29 | 25 | 117 | 49 | 466 | 73 | 1865 | 97 | 7459 | 121 | 29834 |
| B | 2 | 31 | 26 | 123 | 50 | 494 | 74 | 1976 | 98 | 7902 | 122 | 31609 |
| C | 3 | 33 | 27 | 131 | 51 | 523 | 75 | 2093 | 99 | 8372 | 123 | 33488 |
| Db | 4 | 35 | 28 | 139 | 52 | 554 | 76 | 2217 | 100 | 8870 | 124 | 35479 |
| D | 5 | 37 | 29 | 147 | 53 | 587 | 77 | 2349 | 101 | 9397 | 125 | 37589 |
| Eb | 6 | 39 | 30 | 156 | 54 | 622 | 78 | 2489 | 102 | 9956 | 126 | 39824 |
| E | 7 | 41 | 31 | 165 | 55 | 659 | 79 | 2637 | 103 | 10548 | 127 | 42192 |
| F | 8 | 44 | 32 | 175 | 56 | 698 | 80 | 2794 | 104 | 11175 | | |
| Gb | 9 | 46 | 33 | 185 | 57 | 740 | 81 | 2960 | 105 | 11840 | | |
| G | 10 | 49 | 34 | 196 | 58 | 784 | 82 | 3136 | 106 | 12544 | | |
| Ab | 11 | 52 | 35 | 208 | 59 | 831 | 83 | 3322 | 107 | 13290 | | |
| A | 12 | 55 | 36 | 220 | 60 | 880 | 84 | 3520 | 108 | 14080 | | |
| Bb | 13 | 58 | 37 | 233 | 61 | 932 | 85 | 3729 | 109 | 14917 | | |
| B | 14 | 62 | 38 | 247 | 62 | 988 | 86 | 3951 | 110 | 15804 | | |
| C | 15 | 65 | 39 | 262 | 63 | 1047 | 87 | 4186 | 111 | 16744 | | |
| Db | 16 | 69 | 40 | 277 | 64 | 1109 | 88 | 4435 | 112 | 17740 | | |
| D | 17 | 73 | 41 | 294 | 65 | 1175 | 89 | 4699 | 113 | 18795 | | |
| Eb | 18 | 78 | 42 | 311 | 66 | 1245 | 90 | 4978 | 114 | 19912 | | |
| E | 19 | 82 | 43 | 330 | 67 | 1319 | 91 | 5274 | 115 | 21096 | | |
| F | 20 | 87 | 44 | 349 | 68 | 1397 | 92 | 5588 | 116 | 22351 | | |
| Gb | 21 | 92 | 45 | 370 | 69 | 1480 | 93 | 5920 | 117 | 23680 | | |
| G | 22 | 98 | 46 | 392 | 70 | 1568 | 94 | 6272 | 118 | 25088 | | |
| Ab | 23 | 104 | 47 | 415 | 71 | 1661 | 95 | 6645 | 119 | 26580 | | |

Table 1 provides a full set of defined frequencies; however, the hardware or speaker 306 may not generate all frequencies, and the frequencies generated may not exactly match the frequencies listed. Generally, lower frequency numbers produce lower tones, and higher frequency numbers produce higher tones.

It is to be understood that the present invention is not limited to the exact frequencies listed in Table 1. Alternate embodiments may employ more or less frequencies as dictated by the application.

Duration usage is defined as the number of milliseconds for which a sound is to be generated, within a given range of values. A duration usage range is between 0 and 1023 milliseconds in a preferred embodiment.

Volume usage is defined as a number between given limits corresponding to the relative loudness with which to generate the sound. A preferred embodiment specifies the volume usage limits as 0 and 15.

It is to be understood that the values and ranges provided above for frequency, duration, and volume are not intended to be limiting. Other values may be used depending on the implementation and tone to be generated. Further, equation 1 may be replaced or modified depending on the number and range of notes to be generated.

Several different schemes may be used to transmit the usage values, i.e., frequency, duration, and volume, over the USB connection. In one embodiment, the duration value may be transmitted using an 8-bit field (single byte) or in a 16-bit field (double byte), depending on the range of values permitted.

Additionally, the three values may be transmitted in a different order or sequence, e.g., frequency, duration, volume or duration, frequency, volume. The data encoding and transmission strategy used is defined in the USB HID class specification and is not critical to the operation of the present invention.

An exemplary implementation of a preferred embodiment of the present invention is now described.

Speaker controller 304 has no static memory and does not retain any settings after power loss. Thus, each time the system 200 to which keyboard 214 is connected is powered-up, or any time keyboard 214 is connected to a powered system, speaker controller 304 must be informed of any pertinent settings. In a preferred embodiment, the functionality of providing settings to speaker controller 304 is performed by using an ActiveX/COM control object or executable software, known as UsbKeyboardCtl, providing a mechanism by which to set the keyboard features of “key click sound.”

Keyboard 214 defaults to a specific key click sound. For specific embodiments in which a different key click sound is desired, the UsbKeyboardCtl provides a means by which speaker controller 304 is configured.

Speaker controller 304 is configurable by the UsbKeyboardCtl software component and a UsbKeyClickCtl software component, described in detail below. The UsbKeyboardCtl control is independent of other software components; however, other components are required to exercise the functionality of this component and are known to persons of ordinary skill in this art.

UsbKeyClickCtl may be invoked by: an application, e.g., SetUsbKeyClick, by appropriate enterprise management software, e.g., Fit Client Manager available from NCR, Inc., through a browser interface, or by an application able to load and exercise an ActiveX/COM control object.

UsbKeyClickCtl is an ActiveX control providing access to a method for setting the key clicks, i.e., SetClicks.

The SetClicks method examines all currently-enumerated HIDs connected to computer system 200 and finds the HIDs having a Vendor-ID equal to a particular HID vendor's assigned Vendor ID, e.g., 0x0404 in hexadecimal. Among all qualified devices found, each HID 214 is queried for a particular click information setting, i.e., a KEY_CLICK_INFO feature report containing Volume, Frequency, and Duration usages. The volume setting is specified by a value between 0 and 15. The frequency setting is specified by a value between 27 Hertz and 42.192 kHz. The duration setting is specified by a value of 0 to 1023 milliseconds. When a matching device is found, e.g., keyboard 214, the device's product ID (PID) is used to locate key click parameters within computer system 200 memory, e.g., the Registry. The values found in the Registry are sent to the device, i.e., keyboard 214, in the KEY_CLICK_INFO feature report.

Each time SetClicks is invoked, the method reads volume, frequency, and duration key click values or parameters from the Registry. If these parameters are not found in the Registry, default values are written to the Registry, and these default values are transmitted to keyboard 302. By this process, the Registry contains the values most recently sent to HID 214.

In one preferred embodiment, the default values for volume, frequency, and duration, are 15, 1318, and 16, respectively. In this embodiment, duration and volume are set to zero to turn off key click sounds.

It will be readily seen by one of ordinary skill in the art that the present invention fulfills all of the objects set forth above. After reading the foregoing specification, one of ordinary skill will be able to affect various changes, substitutions of equivalents and various other aspects of the invention as broadly disclosed herein. It is therefore intended that the protection granted hereon be limited only by the definition contained in the appended claims and equivalents thereof.

What is claimed is:

1. A method of transmitting tones to a human interface device coupled via universal serial bus, the method comprising:
transmitting tone information using a keyboard tone usage.

2. The method as claimed in claim 1, wherein the tone information includes volume, duration, and frequency values.

3. The method as claimed in claim 1, wherein the keyboard tone usage is a key click info usage.

4. The method as claimed in claim 3, wherein the key click info usage is a collection of a frequency usage, a duration usage, and a volume usage.

5. The method as claimed in claim 3, further comprising:
storing the transmitted key click info usage transmission at the human interface device.

6. The method as claimed in claim 5, further comprising:
generating a tone at the human interface device based on the stored key click info usage.

7. The method as claimed in claim 6, wherein the tone generation step is performed responsive to a user manipulating the human interface device.

8. The method as claimed in claim 1, wherein the keyboard tone usage is an error tone usage.

9. The method as claimed in claim 8, wherein the error tone usage is a collection of a frequency usage, a duration usage, and a volume usage.

10. The method as claimed in claim 8, further comprising:
generating a tone at the human interface device based on the transmitted error tone usage.

11. A method of generating a tone from a USB keyboard responsive to manipulation of a key on the keyboard, wherein the keyboard includes a speaker unit, the method comprising the following steps:
detecting a key manipulation at the keyboard;
determining a keyboard tone information corresponding to the detected key manipulation; and
generating a tone from the speaker unit responsive to the detected key manipulation and based on the keyboard tone information.

12. The method as claimed in claim 11, wherein the keyboard tone information includes volume, frequency, and duration values.

13. The method as claimed in claim 11, wherein the speaker unit includes a speaker controller and a speaker.

14. A method of setting a USB keyboard to generate a tone responsive to manipulation of a key on the keyboard, wherein the keyboard includes a speaker unit, the method comprising the following steps:
detecting a connected keyboard having a speaker unit;
determining a keyboard tone usage corresponding to the detected keyboard; and
transmitting the keyboard tone usage to the keyboard.

15. The method as claimed in claim 14, wherein the keyboard tone usage includes a volume usage, frequency usage, and duration usage.

16. The method as claimed in claim 14, wherein the speaker unit includes a speaker controller and a speaker.

17. The method as claimed in claim 14, wherein the keyboard tone usage is a key click info usage.

18. The method as claimed in claim 14, further comprising:
storing the keyboard tone usage at the keyboard.

19. The method as claimed in claim 18, further comprising:
responsive to a key manipulation on the keyboard, generating a tone based on the stored keyboard tone usage.

20. The method as claimed in claim 14, wherein the keyboard tone usage is an error tone usage.

21. A keyboard for generating a tone responsive to manipulation of a key on the keyboard, comprising:
a plurality of keys;
a programmable component responsive to key manipulation;
a data connection adapted to interface with a computer and pass keyboard tone usages; and
a speaker coupled to the programmable component driving a signal responsive to a key manipulation.

22. The keyboard as claimed in claim 21, wherein the data connection is a universal serial bus connection.

23. The keyboard as claimed in claim 21, wherein the programmable component is a field programmable gate array.

24. The keyboard as claimed in claim 21, wherein the programmable component stores keyboard tone usages.

25. The keyboard as claimed in claim 21, wherein the keyboard tone usage is one of a key click info usage and an error tone usage.

26. The keyboard as claimed in claim 21, wherein the keyboard tone usage includes volume, duration, and frequency values.

27. A computer readable medium, comprising:
at least one sequence of machine executable instructions;
at least one keyboard tone usage;
a medium bearing the executable instructions in machine form and keyboard tone usage, wherein execution of the instructions by one or more processors causes the one or more processors to:
detect a connected keyboard device having a speaker;
determine a keyboard tone usage corresponding to the detected keyboard device; and
transmit the keyboard tone usage to the keyboard device.

28. The computer readable medium as claimed in claim 27, wherein the keyboard tone usage includes a volume usage, a duration usage, and a frequency usage.

29. A computer system, comprising:
a processor;
a keyboard coupled to the processor and having a speaker and programmable component; and
a memory coupled to the processor, the memory having stored therein sequences of instructions, which when executed by the processor, causes the processor to perform the steps of:
determining keyboard identifying information;
determining a keyboard tone usage corresponding to the keyboard identifying information; and
transmitting the keyboard tone usage to the programmable component.

30. The computer system as claimed in claim 29 wherein the keyboard tone usage includes volume, duration, and frequency values.

31. The computer system as claimed in claim 29, wherein the keyboard tone usage is one of a key click info usage and an error tone usage.

32. The computer system as claimed in claim 29, wherein the memory further comprises instructions causing the processor to perform the steps of:
storing the keyboard tone usage at the programmable component; and
responsive to manipulation of a key on the keyboard, generating a tone at the keyboard based on the stored keyboard tone usage.
